(19) United States
(12) Patent Application Publication
(10) Pub. No.: US 2002/0005584 A1
(43) Pub. Date: Jan. 17, 2002

(54) Semiconductor device

(76) Inventor: Shinichi Domae, Hirakata-shi (JP)

Correspondence Address: NIXON PEABODY, LLP, 8180 GREENSBORO DRIVE, SUITE 800, MCLEAN, VA, 22102, US

(21) Appl. No.: 09/824,689

(22) Filed: Apr. 4, 2001

(30) Foreign Application Priority Data
Jul. 12, 2000 (JP) 2000-211064

(51) Int. Cl. H01L 23/48; H01L 23/52; H01L 29/40

(52) U.S. Cl. 257/758

(57) ABSTRACT

An interlayer insulating film of a first insulating material is formed between a lower interconnect layer and an upper interconnect layer in a pad region on a semiconductor substrate. An interconnect insulating film of a second insulating material is formed between adjacent interconnects in an interconnect layer in a signal delay preventing region on the semiconductor substrate. The first insulating material has higher mechanical strength than the second insulating material, and the second insulating material has a lower dielectric constant than the first insulating material.

### BACKGROUND OF THE INVENTION

The present invention relates to a semiconductor device having a multi-level interconnect structure.

In accordance with increase of the density of a semiconductor integrated circuit device, the so-called multi-level interconnect structure formed by stacking interconnect layers in multiple levels has been recently employed in a semiconductor integrated circuit device.

In the multi-level interconnect structure, as the distance between interconnect layers, namely, the thickness of an interlayer insulating film, and the distance between interconnects, namely, the thickness of an insulating film between the interconnects (hereinafter referred to as the interconnect insulating film), are smaller, a problem of signal delay arises more conspicuously. In particular, in an interconnect for transferring a signal to a long distance, the interconnect resistance (R) and the capacitance (C) between interconnect layers and between interconnects are both large, and hence, signal delay time (hereinafter referred to as the RC delay time) is much larger than in the other interconnects. Also, signal delay in a critical path (a path determining the operation speed (clock cycle) of the system among a series of paths of circuit devices and interconnects disposed between the output of a flip-flop and the input of the flip-flop) is a factor in limiting the operation speed of the integrated circuit.

Accordingly, in a current semiconductor integrated circuit device, it is significant to decrease the RC delay time. In order to decrease the RC delay time, it is necessary to decrease the interconnect resistance and the capacitance between interconnect layers and between interconnects.

For example, Japanese Laid-Open Patent Publication No. 11-87510 describes means for decreasing the RC delay time as follows: An underlying insulating film formed below an interconnect layer is trenched in a region between interconnects, and a low-dielectric constant film is deposited between the interconnects and on the interconnect layer. Thus, the parasitic capacitance between the interconnects is decreased, resulting in decreasing the RC delay time.

Also in Japanese Laid-Open Patent Publication No. 11-87510, copper interconnect principally including copper are used for specific interconnects such as a signal line with a large length and a clock line, so as to decrease the interconnect resistance. Thus, the RC delay time is decreased.

When a low-dielectric constant film with a lower dielectric constant than a silicon oxide film is used as an interlayer insulating film, that is, an insulating film between interconnect layers or an interconnect insulating film, that is, an insulating film between interconnects as described above, the capacitance between the interconnects can be decreased, and hence, the RC delay time can be decreased.

A low-dielectric constant film is, however, generally poor in mechanical strength and thermal conductivity. Therefore, when low-dielectric constant films are used for all the interlayer insulating films and interconnect insulating films in a semiconductor integrated circuit device, the following problems arise:

A pad formed in the uppermost layer of a semiconductor integrated circuit device having the multi-level interconnect structure is given impact in a packaging process such as a wire-bonding process or a bumping process. Therefore, large mechanical stress is applied to a pad region of the semiconductor device. However, low-dielectric constant films used for the interlayer insulating films and the interconnect insulating films are inferior in the mechanical strength to a silicon oxide film or the like, and hence are difficult to resist against the mechanical stress applied in the packaging process. As a result, the reliability of the semiconductor device is disadvantageously lowered.

Furthermore, in a power line for supplying a supply voltage or a ground voltage (herein, a line for supplying a supply voltage or a ground voltage is simply designated as a power line), Joule heat is generated because a large current flows therein. Therefore, the temperature is increased in a power line region of a semiconductor device. However, low-dielectric constant films used for the interlayer insulating films and the interconnect insulating films have lower thermal conductivity than a silicon oxide film or the like, and hence, the heat generated in the power line region is difficult to conduct to the semiconductor substrate. Therefore, the temperature is increased in the power line, which also disadvantageously lowers the reliability of the semiconductor device.

### SUMMARY OF THE INVENTION

In consideration of the aforementioned problems, a first object of the invention is realizing both decrease of the RC delay time and increase of the mechanical strength of a pad region, and a second object is realizing both decrease of the RC delay time and improvement of the heat conducting property of a power line region.

In order to achieve the first object, the first semiconductor device of this invention comprises an interlayer insulating film formed from a first insulating material between a lower interconnect layer and an upper interconnect layer in a pad region on a semiconductor substrate; and an interconnect insulating film formed from a second insulating material between adjacent interconnects in an interconnect layer in a signal delay preventing region on the semiconductor substrate, and the first insulating material has higher mechanical strength than the second insulating material, and the second insulating material has a lower dielectric constant than the first insulating material.

A signal delay preventing region herein means a region where RC delay time is desired to be decreased.

In the first semiconductor device of this invention, the interlayer insulating film of the first insulating material with high mechanical strength is provided between the lower interconnect layer and the upper interconnect layer in the pad region on the semiconductor device. Therefore, mechanical stress applied in receiving impact in a packaging process can be reduced because of the high mechanical strength of the interlayer insulating film.

Also, the interconnect insulating film of the second insulating material with a low dielectric constant is formed between the adjacent interconnects in the interconnect layer of the signal delay preventing region on the semiconductor substrate. Therefore, parasitic capacitance between the interconnects can be lowered so as to decrease the RC delay time because of the low dielectric constant of the interconnect insulating film.

As a result, the reliability of the semiconductor device can be largely improved.

In order to achieve the second object, the second semiconductor device of this invention comprises an interlayer insulating film formed from a first insulating material between a lower interconnect layer and an upper interconnect layer in a power line region on a semiconductor substrate; and an interconnect insulating film formed from a second insulating material between adjacent interconnects in an interconnect layer in a signal delay preventing region on the semiconductor substrate, and wherein the first insulating material has higher thermal conductivity than the second insulating material, and the second insulating material has a lower dielectric constant than the first insulating material.

In the second semiconductor device of this invention, the interlayer insulating film of the first insulating material with high thermal conductivity is provided between the lower interconnect layer and the upper interconnect layer in the power line region on the semiconductor substrate, and hence, the interlayer insulating film is good in the thermal conductivity. Therefore, Joule heat generated from a power line can be rapidly conducted to the semiconductor substrate, so that the temperature of the power line region can be minimally increased.

Also, the interconnect insulating film of the second insulating material with a low dielectric constant is formed between the adjacent interconnects in the interconnect layer of the signal delay preventing region on the semiconductor substrate. Therefore, the parasitic capacitance between the interconnects can be lowered so as to decrease the RC delay time because of the low dielectric constant of the interconnect insulating film.

Furthermore, the interlayer insulating film of the first insulating material with high thermal conductivity is provided in the power line region. The first insulating material with high thermal conductivity does not generally have a low dielectric constant, and hence, the parasitic capacitance between the interconnects is comparatively large in the power line region. Therefore, the waveform of voltage variation becomes dull, resulting in stabilizing the power voltage.

Accordingly, the reliability of the semiconductor device can be largely improved.

In the first semiconductor device, the first insulating material is preferably sandwiched also between adjacent interconnects in one of the upper interconnect layer and the lower interconnect layer in the pad region.

In this manner, the first insulating material with high mechanical strength can be provided between the interconnects, so that the mechanical stress applied to the pad region in receiving the impact in the packaging process can be further reduced. As a result, the reliability of the semiconductor device can be further improved.

In the second semiconductor device, the first insulating material is preferably sandwiched between adjacent interconnects in one of the upper interconnect layer and the lower interconnect layer in the power line region.

In this manner, the first insulating material with high thermal conductivity can be provided also between the interconnects, so that the Joule heat generated from the power line can be further rapidly conducted to the semiconductor substrate. As a result, the temperature of the power line region can be further minimally increased.

In the first or second semiconductor device, an interlayer insulating film formed between the interconnect layer and an upper layer or a lower layer in the signal delay preventing region is preferably made from the second insulating material.

In this manner, since the interlayer insulating film is made from the second insulating material with a low dielectric constant, the parasitic capacitance between the interconnects formed adjacent to each other in the vertical direction can be also lowered. As a result, the RC delay time can be further decreased.

In the first or second semiconductor device, it is preferred that the first insulating material is silicon dioxide, fluorosilicate glass or SiOₓH_{y}C_{z}, wherein 0<x<1, 0<y<1 and 0<z<2, and that the second insulating material is an organic polymer, amorphous carbon or a porous material.

In this manner, a combination of the first insulating material with relatively high mechanical strength and the second insulating material with a relatively low dielectric constant can be definitely realized in the first semiconductor device, and a combination of the first insulating material with relatively high thermal conductivity and the second insulating material with a relatively low dielectric constant can be definitely realized in the second semiconductor device.

In the first or second semiconductor device, it is preferred that the first insulating material is silicon dioxide or fluorosilicate glass, and that the second insulating material is SiOₓH_{y}C_{z}, wherein 0<x<1, 0<y<1 and 0<z<2.

In this manner, a combination of the first insulating material with relatively high mechanical strength and the second insulating material with a relatively low dielectric constant can be definitely realized in the first semiconductor device, and a combination of the first insulating material with relatively high thermal conductivity and the second insulating material with a relatively low dielectric constant can be definitely realized in the second semiconductor device.

In order to achieve the first object, the third semiconductor device of this invention comprises an interlayer insulating film formed from an insulating material between a lower interconnect layer and an upper interconnect layer in a pad region on a semiconductor substrate; and an interconnect insulating film having an air gap between adjacent interconnects in an interconnect layer in a signal delay preventing region on the semiconductor substrate.

In the third semiconductor device of this invention, the interlayer insulating film with higher mechanical strength than the air gap is provided between the lower interconnect layer and the upper interconnect layer in the pad region on the semiconductor substrate. Therefore, the mechanical stress in receiving the impact in the packaging process can be lowered because of the high mechanical strength of the interlayer insulating film.

Also, the interconnect insulating film formed between the adjacent interconnects in the interconnect layer of the signal delay preventing region on the semiconductor substrate has the air gap with a very low dielectric constant. Therefore, the parasitic capacitance between the interconnects can be lowered so as to decrease the RC delay time because of the low dielectric constant of the interconnect insulating film.

As a result, the reliability of the semiconductor device can be largely improved.

In order to achieve the second object, the fourth semiconductor device of this invention comprises an interlayer insulating film formed from an insulating material between a lower interconnect layer and an upper interconnect layer in a power line region on a semiconductor substrate; and an interconnect insulating film having an air gap between adjacent interconnects in an interconnect layer in a signal delay preventing region on the semiconductor substrate.

In the fourth semiconductor device, the interlayer insulating film with higher thermal conductivity than the air gap is provided between the lower interconnect layer and the upper interconnect layer in the power line region on the semiconductor substrate. Therefore, the Joule heat generated from the power line can be rapidly conducted to the semiconductor substrate, so that the temperature of the power line region can be minimally increased.

Also, the interconnect insulating film formed between the adjacent interconnects in the interconnect layer of the signal delay preventing region on the semiconductor substrate has the air gap with a very low dielectric constant, and hence, the interconnect insulating film has a low dielectric constant. Therefore, the parasitic capacitance between the interconnects can be lowered so as to decrease the RC delay time.

As a result, the reliability of the semiconductor device can be largely improved.

In the third semiconductor device, the insulating material is preferably sandwiched between adjacent interconnects in one of the upper interconnect layer and the lower interconnect layer in the pad region.

In this manner, the insulating material with higher mechanical strength than the air gap is provided also between the interconnects. Therefore, the mechanical stress applied to the pad region in receiving the impact in the packaging process can be further reduced, so that the reliability of the semiconductor device can be further improved.

In the fourth semiconductor device, the insulating material is preferably sandwiched between adjacent interconnects in one of the upper interconnect layer and the lower interconnect layer in the power line region.

In this manner, the insulating material with higher thermal conductivity than the air gap is provided also between the interconnects. Therefore, the Joule heat generated from the power line can be more rapidly conducted to the semiconductor substrate, so that the temperature of the power line region can be further minimally increased.

In the third or fourth semiconductor device, an interlayer insulating film formed between the interconnect layer and an upper layer or a lower layer in the signal delay preventing region is preferably made from a material having a lower dielectric constant than the insulating material.

In this manner, the dielectric constant of the interlayer insulating film can be lowered, so as to lower the parasitic capacitance between the interconnects adjacent to each other in the vertical direction. As a result, the RC delay time can be further decreased.

In the first or third semiconductor device, the signal delay preventing region preferably corresponds to a region on the semiconductor substrate excluding the pad region.

In this manner, the mechanical strength can be increased or the thermal conductivity can be decreased in the region excluding the pad region.

In the second or fourth semiconductor device, the signal delay preventing region preferably corresponds to a region on the semiconductor substrate excluding the power line region.

In this manner, the mechanical strength can be increased or the thermal conductivity can be decreased in the region excluding the power line region.

In any of the first through fourth semiconductor devices, the signal delay preventing region preferably corresponds to a functional block region.

In this manner, the parasitic capacitance between interconnects of the functional block can be lowered, so as to decrease the RC delay time in the functional block region.

In any of the first through fourth semiconductor devices, the signal delay preventing region preferably corresponds to a memory block region.

In this manner, the parasitic capacitance between interconnects of a memory cell such as a DRAM, an SRAM and a ROM, so as to decrease the RC delay time in the memory block region. In addition, noise in a signal line can be reduced.

In any of the first through fourth semiconductor devices, the signal delay preventing region preferably corresponds to a critical path region.

In this manner, the parasitic capacitance between interconnects of the critical path can be lowered, so as to decrease the RC delay time in the critical path region.

### BRIEF DESCRIPTION OF THE DRAWINGS

FIG. 1A is a plane view for showing a first plane layout of a pad region and a signal delay preventing region on a semiconductor substrate, FIG. 1B is a circuit diagram for showing composing elements of the pad region and FIG. 1C is a plane view for showing a second plane layout of a pad region, a power line region and a signal delay preventing region on a semiconductor substrate;

FIG. 2A is a plane view for showing a third plane layout of a pad region, a power line region and a signal delay preventing region on a semiconductor substrate and FIG. 2B is a plane view for showing a fourth plane layout of a pad region, a power line region and a signal delay preventing region on a semiconductor substrate;

FIG. 3 is a cross-sectional view for showing a first cross-sectional structure of a semiconductor device including a pad region, a power line region and a signal delay preventing region;

FIG. 4 is a cross-sectional view for showing a second cross-sectional structure of a semiconductor device including a pad region, a power line region and a signal delay preventing region;

FIG. 5 is a cross-sectional view for showing a third cross-sectional structure of a semiconductor device including a pad region, a power line region and a signal delay preventing region;

FIGS. 6A, 6B and 6C are cross-sectional views taken on different lines from the first through third cross-sectional structures of a semiconductor device including a power line region and a signal delay preventing region according to Embodiment 1;

FIGS. 7A, 7B and 7C are cross-sectional views for showing procedures in a method for fabricating the semiconductor device having the cross-sectional structure of FIG. 6B;

FIGS. BA, 8B and 8C are cross-sectional views for showing other procedures in the method for fabricating the semiconductor device having the cross-sectional structure of FIG. 6B;

FIGS. 9A, 9B and 9C are cross-sectional views taken on different lines from the first through third cross-sectional structures of a semiconductor device including a power line region and a signal delay preventing region according to Embodiment 2; and

FIGS. 10A and 10B are cross-sectional views for showing procedures in a method for fabricating a semiconductor device having the cross-sectional structure of FIG. 9B.

### DETAILED DESCRIPTION OF THE INVENTION

Embodiment 1

In a first exemplified semiconductor device according to Embodiment 1 of the invention, an interlayer insulating film of a first insulating material is formed between a lower interconnect layer and an upper interconnect layer in a pad region on a semiconductor substrate, and an interconnect insulating film of a second insulating material sandwiched between adjacent interconnects is formed in an interconnect layer in a signal delay preventing region where signal delay is desired to be prevented on the semiconductor substrate. The first insulating material has higher mechanical strength than the second insulating material and the second insulating material has a lower dielectric constant than the first insulating material.

In a second exemplified semiconductor device according to Embodiment 1, an interlayer insulating film of the first insulating material is formed between a lower interconnect layer and an upper interconnect layer in a power line region on a semiconductor substrate, and an interconnect insulating film of the second insulating material sandwiched between adjacent interconnects is formed in an interconnect layer in a signal delay preventing region where the signal delay is desired to be prevented on the semiconductor substrate. The first insulating material has higher thermal conductivity than the second insulating material and the second insulating material has a lower dielectric constant than the first insulating material.

A first combination of the first insulating material and the second insulating material, which are used in both the first and second exemplified semiconductor devices, will now be described.

Examples of the first insulating material usable in the first combination are silicon dioxide (SiO₂), fluorosilicate glass (FSG) and SiOₓH_{y}C_{z}, (wherein 0<x<1, 0<y<1 and 0<z<2). Silicon dioxide may be obtained by any of various CVD and may include no impurity or an impurity such as boron and phosphorus.

Examples of the second insulating material usable in the first combination are organic polymers such as poly(allyl ether) (PAE) and benzocyclobutane (BCB), amorphous carbon and a porous material.

In the first combination, the first insulating material has higher mechanical strength and higher thermal conductivity than the second insulating material, and the second insulating material has a lower dielectric constant than the first insulating material.

A second combination of the first insulating material and the second insulating material, which are used in both the first and second exemplified semiconductor devices, will now be described.

Examples of the first insulating material usable in the second combination are silicon dioxide (SiO₂) and fluorosilicate glass (FSG). Silicon dioxide may be obtained by any of various CVD, and may include no impurity or an impurity such as boron and phosphorus.

An example of the second insulating material usable in the second combination is SiOₓH_{y}C_{z} (wherein 0<x<1, 0<y<1 and 0<z<2).

In the second combination, the first insulating material has higher mechanical strength and higher thermal conductivity than the second insulating material, and the second insulating material has a lower dielectric constant than the first insulating material.

Accordingly, since the interlayer insulating film of the first insulating material having high mechanical strength is formed between the lower interconnect layer and the upper interconnect layer in the pad region on the semiconductor substrate in the first exemplified semiconductor device, the interlayer insulating film is good in the mechanical strength. Also, since the interconnect insulating film of the second insulating material having a low dielectric constant is sandwiched between the adjacent interconnects in the interconnect layer of the signal delay preventing region on the semiconductor substrate, the interconnect insulating film has a low dielectric constant.

Accordingly, since the mechanical strength is improved in the pad region, even when the pad region is given impact in a packaging process, the mechanical stress can be lowered. Also, since the dielectric constant of the interconnect insulating film is lowered in the signal delay preventing region, the parasitic capacitance between the interconnects can be reduced so as to decrease the RC delay time. As a result, the reliability of the first exemplified semiconductor device can be improved.

Furthermore, since the interlayer insulating film of the first insulating material having high thermal conductivity is formed between the lower interconnect layer and the upper interconnect layer in the power line region on the semiconductor substrate in the second exemplified semiconductor device, the interlayer insulating film is good in the thermal conductivity. Also, the interconnect insulating film of the second insulating material having a low dielectric constant is sandwiched between the adjacent interconnects in the interconnect layer of the signal delay preventing region on the semiconductor substrate, the interconnect insulating film has a low dielectric constant.

Accordingly, since the thermal conductivity is improved in the power line region, the Joule heat generated from a power line can be rapidly conducted to the semiconductor substrate, and hence, the temperature of the power line region is minimally increased. Also, since the interconnect insulating film has a low dielectric constant in the signal delay preventing region, the parasitic capacitance between the interconnects can be reduced so as to decrease the RC delay time. As a result, the reliability of the second exemplified semiconductor device can be improved.

(Layouts)

Now, layouts for embodying the first and second exemplified semiconductor devices of Embodiment 1, namely, layouts of a pad region desired to be improved in the mechanical strength, a power line region desired to be improved in the heat conducting property and a signal delay preventing region desired to be decreased in the parasitic capacitance between interconnects, will be described with reference to the accompanying drawings.

<First Layout>

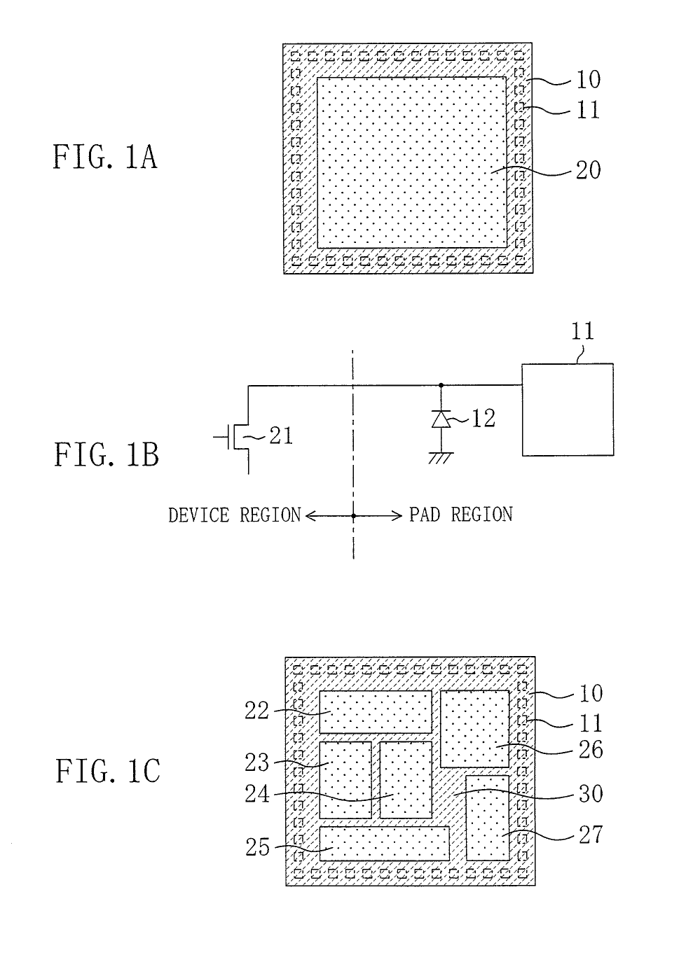

FIG. 1A is a plane view of a first layout of a pad region and a signal delay preventing region. A pad region 10 where bonding pads 11 are formed is provided in a peripheral portion of a semiconductor chip, and a signal delay preventing region including a device region 20 is provided at the center of the semiconductor chip.

In the pad region 10, a bonding pad 11 and a protection circuit 12 are formed as is shown in FIG. 1B. The protection circuit 12 includes a diode or a transistor formed in the vicinity of the bonding pad 11 and prevents a circuit device 21 such as a transistor formed in the device region from being damaged by an unexpected pulse current (designated as a surge current or the like) flowing from the bonding pad 11 into the device region.

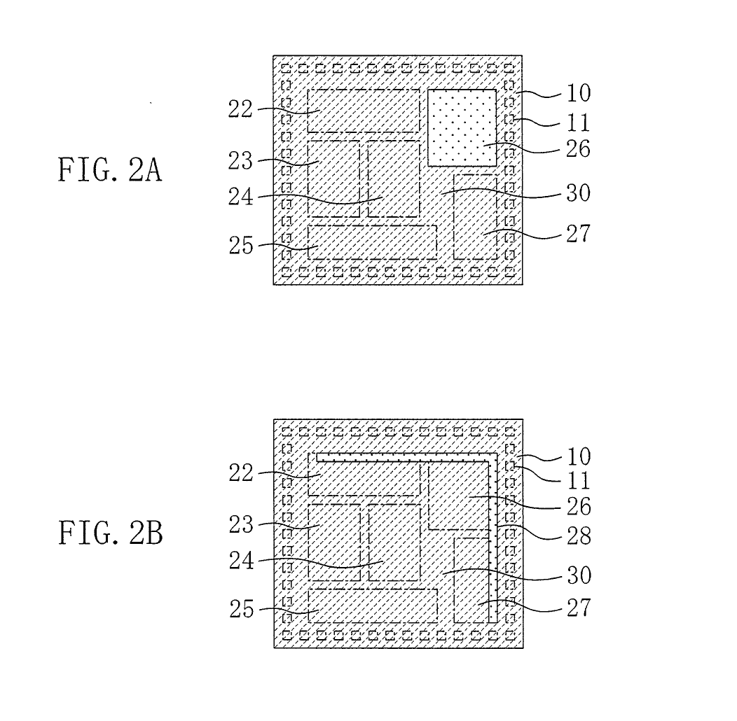

Furthermore, in the device region 20 included in the signal delay preventing region, the circuit device 21 such as a transistor is formed as described above, and specific circuit blocks formed in the device region 20 will be described later with reference to FIGS. 1A, 2A and 2B.

Accordingly, in the first layout, an interlayer insulating film of the first insulating material is formed in the pad region 10, and an interconnect insulating film of the second insulating material is formed between adjacent interconnects in an interconnect layer in the signal delay preventing region (namely, the device region 20).

<Second Layout>

FIG. 1C is a plane view of a second layout of a pad region, a power line region and a signal delay preventing region. Similarly to the first layout, a pad region 10 where bonding pads 11 are formed is provided in a peripheral portion of a semiconductor chip.

The signal delay preventing region corresponds to a first logic circuit block 22, a CPU block 23, an SRAM block 24, an I/O block 25, a DRAM block 26 and a second logic circuit block 27 formed in a device region 20 (shown in FIG. 1A).

The power line region 30 corresponds to a portion of the device region 20 excluding the first logic circuit block 22, the CPU block 23, the SRAM block 24, the I/O block 25, the DRAM block 26 and the second logic circuit block 27.

Accordingly, in the second layout, an interlayer insulating film of the first insulating material is formed in the pad region 10 and the power line region 30, and an interconnect insulating film of the second insulating material is formed between adjacent interconnects in an interconnect layer in the signal delay preventing region (namely, the first logic circuit block 22, the CPU block 23, the SRAM block 24, the I/O block 25, the DRAM block 26 and the second logic circuit block 27).

<Third Layout>

FIG. 2A is a plane view of a third layout of a pad region, a power line region and a signal delay preventing region. Similarly to the first layout, a pad region 10 where bonding pads 11 are formed is provided in a peripheral portion of a semiconductor chip.

The signal delay preventing region corresponds to a DRAM block 26 alone formed in a device region 20 (shown in FIG. 1A).

The power line region 30 corresponds to a portion of the device region 20 excluding a first logic circuit block 22, a CPU block 23, an SRAM block 24, an I/O block 25, the DRAM block 26 and a second logic circuit block 27.

In the first logic circuit block 22, the CPU block 23, the SRAM block 24, the I/O block 25 and the second logic circuit block 27 of the device region 20, an interlayer insulating film of the first insulating material is formed.

Accordingly, in the third layout, an interlayer insulating film of the first insulating material is formed in the pad region 20, the power line region 30, and the first logic circuit block 22, the CPU block 23, the SRAM block 24, the I/O block 25 and the second logic circuit block 27 of the device region 20. An interconnect insulating film of the second insulating material is formed between adjacent interconnects in an interconnect layer in the signal delay preventing region (namely, the DRAM block 26).

The signal delay preventing region may correspond to a memory cell block other than the DRAM block 26, such as an SRAM block and a ROM block.

<Fourth Layout>

FIG. 2B is a plane view of a fourth layout of a pad region and a signal delay preventing region. Similarly to the first layout, a pad region 10 where bonding pads 11 are formed is provided in a peripheral portion of a semiconductor chip.

The signal delay preventing region corresponds to a critical path region 28 alone of a device region 20 (shown in FIG. 1A). A critical path means, as described above, a path determining the operation speed (clock cycle) of the system among a series of paths of circuit devices and lines disposed between the output of a flip-flop and the input of the flip-flop, and specifically appears as a line path having a length larger than a half of the shorter side of the semiconductor chip. Accordingly, when a region where an interconnect having a length larger than a half of the shorter side of the semiconductor chip is formed is defined as the signal delay preventing region, signal delay can be definitely prevented in this region.

In a portion of the device region 20 excluding the critical path region 28, an interlayer insulating film of the first insulating material is formed.

Accordingly, in the fourth layout, an interlayer insulating film of the first insulating material is formed in the pad region 10 and the portion of the device region 20 excluding the critical path region 28, and an interconnect insulating film of the second insulating material is formed between adjacent interconnects in an interconnect layer in the signal delay preventing region (namely, the critical path region 28).

(Cross-sectional Structures)

In each of the first through fourth layouts, the plane layout of one interconnect layer in the multi-level interconnect structure is described. Now, cross-sectional structures of respective interconnect layers in the multi-level interconnect structure for embodying the first and second exemplified semiconductor devices of Embodiment 1 will be described. Specifically, the cross-sectional structures of respective layers in a pad region desired to be improved in the mechanical strength, a power line region desired to be improved in the heat conducting property and a signal delay preventing region desired to be decreased in the parasitic capacitance between interconnects will now be described with reference to the accompanying drawings.

<First Cross-sectional Structure>

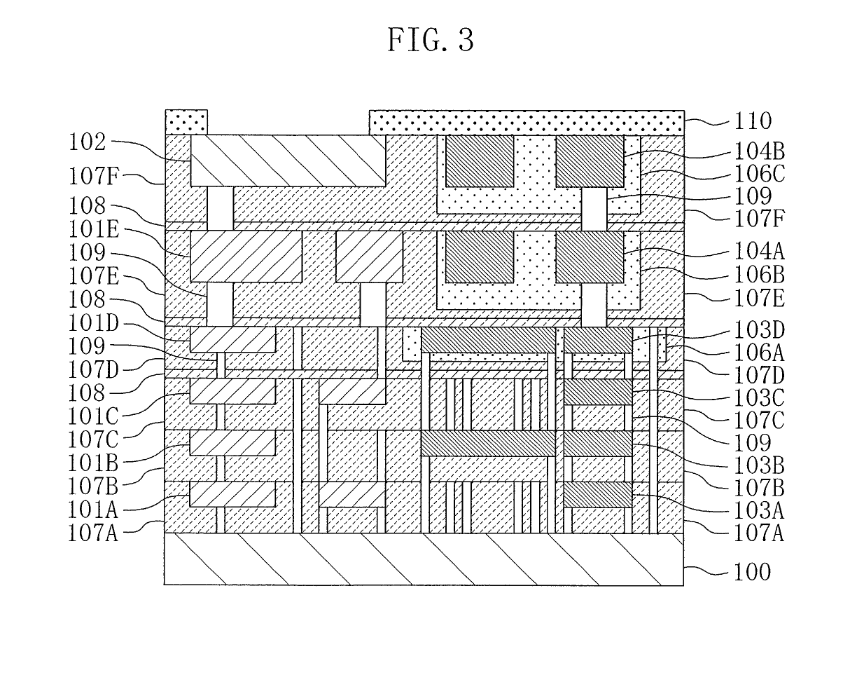

FIG. 3 shows a first cross-sectional structure of a semiconductor device including a pad region, a power line region and a signal delay preventing region. The pad region and the power line region are shown in the left portion of FIG. 3 and the signal delay preventing region is shown in the right portion of FIG. 3. All the power lines and signal lines shown in the first cross-sectional structure are buried interconnects of copper or copper alloy.

In the left portion of FIG. 3, first power lines 101A, second power lines 101B, third power lines 101C, fourth power lines 101D and fifth power lines 101E are successively formed in this order in the upward direction on a semiconductor substrate 100 and bonding pads 102 are formed in the uppermost layer.

In the right portion of FIG. 3, first signal lines 103A, second signal lines 103B, third signal lines 103C, fourth signal lines 103D, first critical lines 104A and second critical lines 104B are successively formed in this order in the upward direction on the semiconductor substrate 100.

A first low-dielectric constant insulating film 106A of the second insulating material is formed below and between the fourth signal lines 103D. A second low-dielectric constant insulating film 106B of the second insulating material is formed below and between the first critical lines 104A. A third low-dielectric constant insulating film 106C of the second insulating material is formed below and between the second critical lines 104B.

A first insulating film 107A of the first insulating material is formed below and between the first power lines 101A and below and between the first signal lines 103A. A second insulating film 107B of the first insulating material is formed below and between the second power lines 101B and below and between the second signal lines 103B. A third insulating film 107C of the first insulating material is formed below and between the third power lines 101C and below and between the third signal lines 103C. A fourth insulating film 107D of the first insulating material is formed below and between the fourth power lines 101D and below the first low-dielectric constant insulating film 106A. A fifth insulating film 107E of the first insulating material is formed below and between the fifth power lines 101E and below the second low-dielectric constant insulating film 106B. A sixth insulating film 107F of the first insulating material is formed below and between the bonding pads 102 and below the third low-dielectric constant film 106C.

Diffusion preventing layers 108 for preventing diffusion of copper are formed on the top faces of the third power lines 101C, the third signal lines 103C and the third insulating film 107C, on the top faces of the fourth power lines 101D, the fourth signal lines 103D, the first low-dielectric constant insulating film 106A and the fourth insulating film 107D, and on the top faces of the fifth power lines 101E, the first critical lines 104A, the second low-dielectric constant insulating film 106B and the fifth insulating film 107E.

Power lines formed adjacent to each other in the vertical direction and set to the same potential are connected to each other through a via 109, and signal lines formed adjacent to each other in the vertical direction and transferring the same signal are connected to each other through a via 109.

A protection insulating film 110 is formed on the top faces of the second critical lines 104B, the third low-dielectric constant insulating film 106C and the sixth insulating film 107F.

Although the pad region and the power line region are adjacent to the signal delay preventing region in the horizontal direction in the aforementioned case, the pad region or the power line region can be adjacent to the signal delay preventing region in the vertical direction, namely, a critical line can be provided below a pad or a power line.

<Second Cross-sectional Structure>

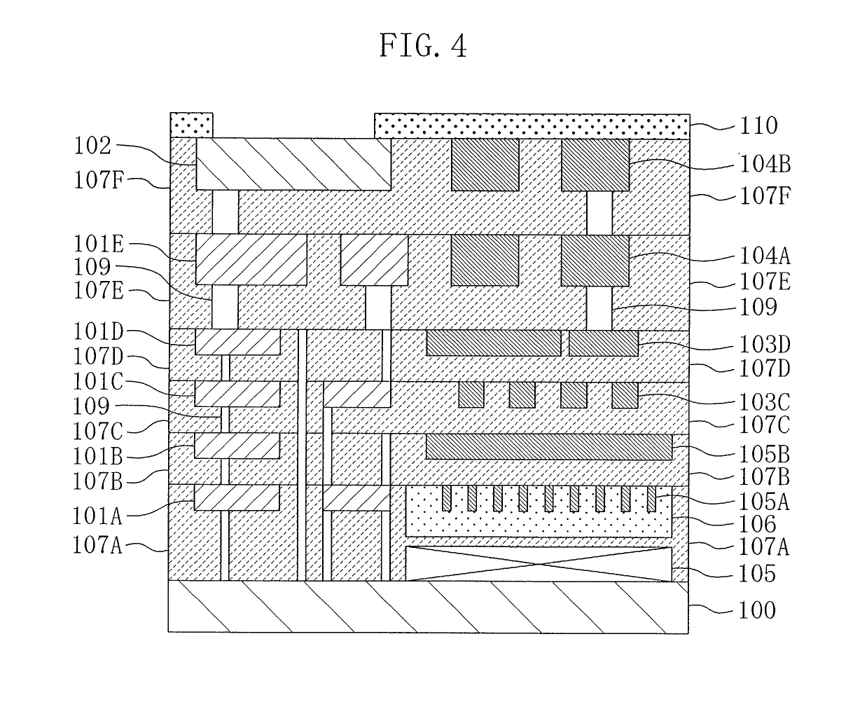

FIG. 4 shows a second cross-sectional structure of a semiconductor device including a pad region, a power line region and a signal delay preventing region. The pad region and the power line region are shown in the left portion of FIG. 4 and the signal delay preventing region is shown in the right portion of FIG. 4. All the power lines and signal lines shown in the second cross-sectional structure are buried interconnects of copper or copper alloy.

In the left portion of FIG. 4, first power lines 101A, second power lines 101B, third power lines 101C, fourth power lines 101D and fifth power lines 101E are successively formed in this order in the upward direction on a semiconductor substrate 100, and bonding pads 102 are formed in the uppermost layer.

In the right portion of FIG. 4, a DRAM block 105, bit lines 105A, word lines 105B, third signal lines 103C, fourth signal lines 103D, first critical lines 104A and second critical lines 104B are successively formed in this order in the upward direction on the semiconductor substrate 100.

A low-dielectric constant insulating film 106 of the second insulating material is formed below and between the bit lines 105A.

A first insulating film 107A of the first insulating material is formed below and between the first power lines 101A and between the DRAM block 105 and the low-dielectric constant insulating film 106. A second insulating film 107B of the first insulating material is formed below and between the second power lines 101B and below and between the word lines 105B. A third insulating film 107C of the first insulating material is formed below and between the third power lines 101C and below and between the third signal lines 103C. A fourth insulating film 107D of the first insulating material is formed below and between the fourth power lines 101D and below and between the fourth signal lines 103D. A fifth insulating film 107E of the first insulating material is formed below and between the fifth power lines 101E and below and between the first critical lines 104A. A sixth insulating film 107F of the first insulating material is formed below and between the bonding pads 102 and below and between the second critical lines 104B.

Power lines formed adjacent to each other in the vertical direction and set to the same potential are connected to each other through a via 109, and signal lines formed adjacent to each other in the vertical direction and transferring the same signal are connected to each other through a via 109.

A protection insulating film 110 is formed on the top faces of the second critical lines 104B and the sixth insulating film 107F.

Although the pad region and the power line region are adjacent to the signal delay preventing region in the horizontal direction in the aforementioned case, the pad region or the power line region can be adjacent to the signal delay preventing region in the vertical direction, namely, a DRAM block can be provided below a pad or a power line.

<Third Cross-sectional Structure>

FIG. 5 shows a third cross-sectional structure of a semiconductor device including a pad region, a power line region and a signal delay preventing region. The pad region and the power line region are shown in the left portion of FIG. 5, and the signal delay preventing region is shown in the right portion of FIG. 5. All the power lines and signal lines shown in the third cross-sectional structure are buried interconnects of copper or copper alloy.

In the left portion of FIG. 5, first power lines 101A, second power lines 101B, third power lines 101C, fourth power lines 101D and fifth power lines 101E are successively formed in this order in the upward direction on a semiconductor substrate 100, and bonding pads 102 are formed in the uppermost layer.

In the right portion of FIG. 5, first signal lines 103A, second signal lines 103B, third signal lines 103C, fourth signal lines 103D, first critical lines 104A and second critical lines 104B are successively formed on the semiconductor substrate 100.

Also, in the entire region excluding a peripheral portion in the right portion of FIG. 5, a first low-dielectric constant insulating film 106A, a second low-dielectric constant insulating film 106B, a third low-dielectric constant insulating film 106C, a fourth low-dielectric constant insulating film 106D, a fifth low-dielectric constant insulating film 106E and a sixth low-dielectric constant insulating film 106F all made from the second insulating material are successively formed in this order in the upward direction.

In the entire region in the left portion of FIG. 5, a first insulating film 107A, a second insulating film 107B, a third insulating film 107C, a fourth insulating film 107D, a fifth insulating film 107E and a sixth insulating film 107F all made from the first insulating material are successively formed in this order in the upward direction.

Power lines formed adjacent to each other in the vertical direction and set to the same potential are connected to each other through a via 109, and signal lines formed adjacent to each other in the vertical direction and transferring the same signal are connected to each other through a via 109.

A protection insulating film 110 is formed on the top faces of the second critical lines 104B, the sixth low-dielectric constant insulating film 106F and the sixth insulating film 107F.

Although the pad region and the power line region are adjacent to the signal delay preventing region in the horizontal direction in the aforementioned case, the pad region or the power line region can be adjacent to the signal delay preventing region in the vertical direction.

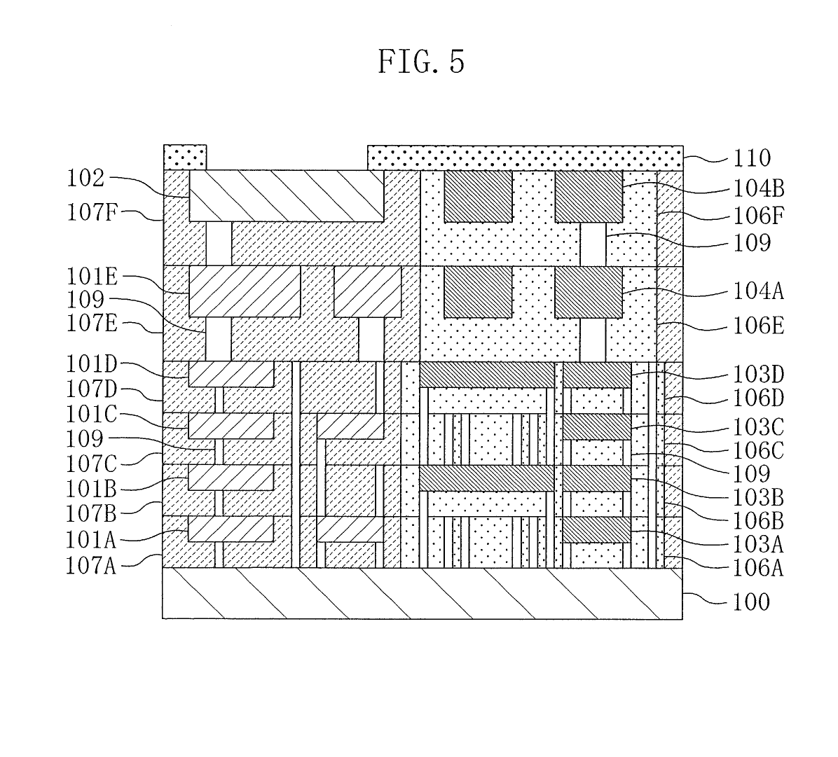

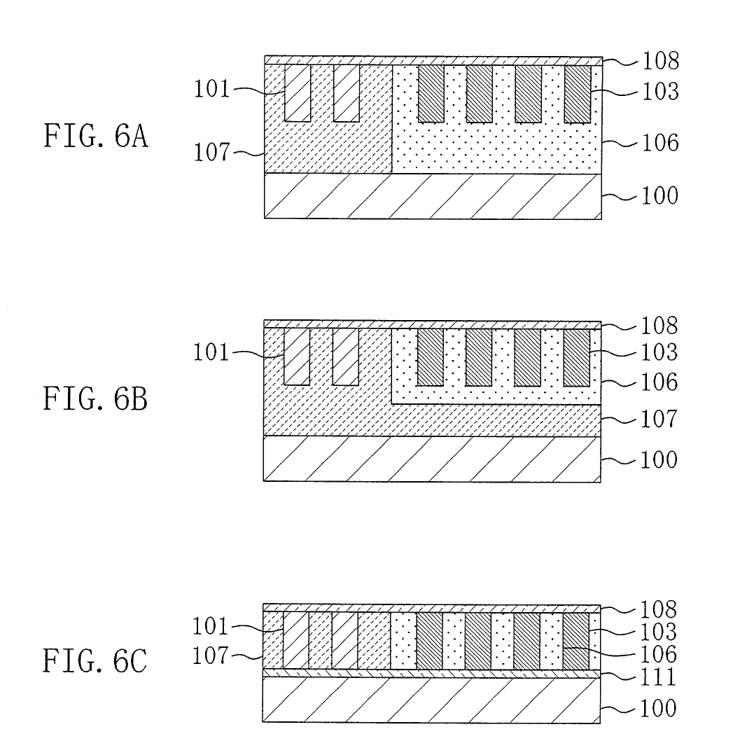

FIGS. 6A through 6C shows cross-sectional structures taken on different lines from the first through third cross-sectional structures in a semiconductor device including a power line region and a signal delay preventing region according to Embodiment 1.

In the cross-sectional structure of FIG. 6A, a low-dielectric constant insulating film 106 of the second insulating material is formed in the entire signal delay preventing region where signal lines 103 of copper or copper alloy are formed, and an insulating film 107 of the first insulating material is formed in the entire power line region where power lines 101 of copper or copper alloy are formed. A diffusion preventing layer 108 of, for example, SiC, SiCN or SiN for preventing diffusion of copper is formed on the power lines 101, the signal lines 103, the low-dielectric constant insulating film 106 and the insulating film 107.

In the cross-sectional structure of FIG. 6B, a low-dielectric constant insulating film 106 of the second insulating material is formed below and between signal lines 103 of copper or copper alloy, and an insulating film 107 of the first insulating film is formed in the entire power line region where power lines 101 of copper or copper alloy are formed and below the low-dielectric constant insulating film 106. A diffusion preventing layer 108 of, for example, SiC, SiCN or SiN for preventing diffusion of copper is formed on the power lines 101, the signal lines 103, the low-dielectric constant insulating film 106 and the insulating film 107.

In the cross-sectional structure of FIG. 6C, a low-dielectric constant insulating film 106 of the second insulating material is formed between signal lines 103 of copper or copper alloy, and an insulating film 107 of the first insulating material is formed between power lines 101 of copper or copper alloy. A diffusion preventing layer 108 of, for example, SiC, SiCN or SiN for preventing diffusion of copper is formed on the power lines 101, the signal lines 103, the low-dielectric constant insulating film 106 and the insulating film 107. Also, an etching stopper layer 111 of, for example, SiC is formed below the power lines 101, the signal lines 103, the low-dielectric constant insulating film 106 and the insulating film 107, and the etching stopper layer 111 works as a stopper in forming, by etching, interconnect grooves for burying the power lines 101 and the signal lines 103. When the etching stopper layer 111 is thus provided below the power lines 101 and the signal lines 103, over-etching can be definitely carried out in forming the interconnect grooves by etching, so as to avoid variation in the depth among the interconnect grooves.

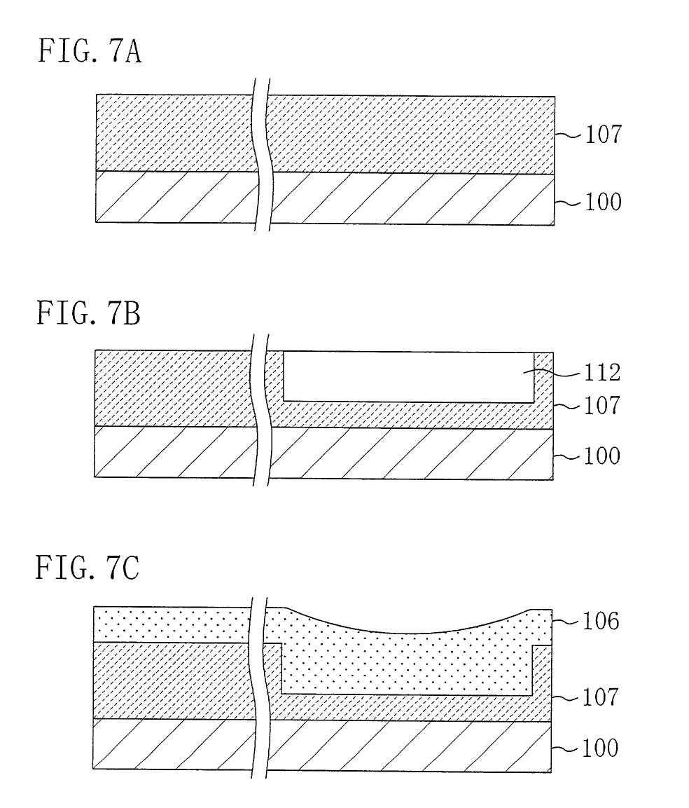

Now, a method for fabricating the semiconductor device having the cross-sectional structure of FIG. 6B will be described with reference to FIGS. 7A through 7C and 8A through 8C.

First, as is shown in FIG. 7A, an insulating film 107 of the first insulating material is formed on the entire top face of a semiconductor substrate 100. Thereafter, the insulating film 107 is selectively etched, thereby forming a recess 112 in a signal delay preventing region (region where signal lines are to be formed) in the insulating film 107 as is shown in FIG. 7B. At this point, the insulating film 107 is allowed to remain below the recess 112 by controlling the etching time.

Next, as is shown in FIG. 7C, a low-dielectric constant insulating film 106 of the second insulating material is formed on the insulating film 107 so as to fill the recess 112. Thereafter, a portion of the low-dielectric constant insulating film 106 formed on the insulating film 107 is removed by, for example, CMP, thereby placing the top face of the low-dielectric constant insulating film 106 at the same level as the top face of the insulating film 107 as is shown in FIG. 8A.

Then, after forming interconnect grooves in the low-dielectric constant film 106 and the insulating film 107, a metal film of copper or copper alloy is deposited on the entire top faces of the low-dielectric constant insulating film 106 and the insulating film 107. Thereafter, a portion of the metal film formed on the low-dielectric constant insulating film 106 and the insulating film 107 is removed by, for example, the CMP. Thus, signal lines 103 are formed in the interconnect grooves of the low-dielectric constant insulating film 106 and power lines 101 are formed in the interconnect grooves of the insulating film 107 as is shown in FIG. 8B.

Subsequently, a diffusion preventing layer 108 for preventing diffusion of copper is formed on the entire top faces of the power lines 101, the signal lines 103, the low-dielectric constant insulating film 106 and the insulating film 107 as is shown in FIG. 8C.

Embodiment 2

In a first exemplified semiconductor device according to Embodiment 2, an interlayer insulating film of an insulating material is formed between a lower interconnect layer and an upper interconnect layer in a pad region on a semiconductor substrate, and an interconnect insulating film having an air gap between adjacent interconnects in an interconnect layer is formed in the interconnect layer of a signal delay preventing region, where signal delay is desired to be prevented on the semiconductor substrate.

In a second exemplified semiconductor device according to Embodiment 2, an interlayer insulating film of an insulating material is formed between a lower interconnect layer and an upper interconnect layer in a power line region on a semiconductor substrate, and an interconnect insulating film having an air gap between adjacent interconnects in an interconnect layer is formed in the interconnect layer of a signal delay preventing region, where signal delay is desired to be prevented on the semiconductor substrate.

Examples of the insulating material of Embodiment 2 are silicon dioxide (SiO₂), fluorosilicate glass (FSG), SiOₓH_{y}C_{z} (wherein 0<x<1, 0<y<1 and 0<z<2), an organic polymer, amorphous carbon and a porous material. Silicon dioxide may be obtained by any of various CVD and may include no impurity or an impurity such as boron and phosphorus. Also, examples of the organic polymer are poly(allyl ether) (PAE) and benzocyclobutane (BCB).

In Embodiment 2, air included in the air gap has a lower dielectric constant than any of the aforementioned insulating materials. Also, any of the aforementioned insulating materials has higher mechanical strength and higher thermal conductivity than the air included in the air gap.

Accordingly, in the first exemplified semiconductor device, the interlayer insulating film having higher mechanical strength than the air gap is formed between the lower interconnect layer and the upper interconnect layer in the pad region on the semiconductor substrate. Also, the interconnect insulating film formed between the adjacent interconnects in the interconnect layer of the signal delay preventing region on the semiconductor substrate has the air gap with a very low dielectric constant, and hence, the interconnect insulating film has a low dielectric constant.

As a result, the mechanical strength is improved in the pad region, and hence, mechanical stress can be lowered even when impact is applied in a packaging process. On the other hand, in the signal delay preventing region, the dielectric constant of the interconnect insulating film is lowered, and hence, the parasitic capacitance between the interconnects is lowered so as to decrease the RC delay time. Thus, the reliability of the first exemplified semiconductor device can be improved.

Alternatively, in the second exemplified semiconductor device, the interlayer insulating film having higher thermal conductivity than the air gap is formed between the lower interconnect layer and the upper interconnect layer in the power line region on the semiconductor substrate. Also, the interconnect insulating film formed between the adjacent interconnects in the interconnect layer of the signal delay preventing region on the semiconductor substrate has the air gap with a very low dielectric constant, and hence, the interconnect insulating film has a low dielectric constant.

As a result, the thermal conductivity is improved in the power line region, and hence, Joule heat generated from a power line can be rapidly conducted to the semiconductor substrate so as to prevent the temperature of the power line region from increasing. Also, in the signal delay preventing region, the dielectric constant of the interconnect insulating film is lowered, and hence, the parasitic capacitance between the interconnects is lowered so as to decrease the RC delay time. Thus, the reliability of the second exemplified semiconductor device can be improved.

Now, layouts for embodying the first and second exemplified semiconductor devices of Embodiment 2, namely, layouts of a pad region desired to be improved in the mechanical strength, a power line region desired to be improved in the heat conducting property and a signal delay preventing region desired to be decreased in the parasitic capacitance between interconnects, will be described.

A first layout of Embodiment 2 is the same as the first layout of Embodiment 1 described with reference to FIG. 1A, and specifically, a pad region 10 is provided in a peripheral portion of a semiconductor chip and a signal delay preventing region including a device region 20 is provided at the center of the semiconductor chip.

A second layout of Embodiment 2 is the same as the second layout of Embodiment 1 described with reference to FIG. 1C, and specifically, a pad region 10 is provided in a peripheral portion of a semiconductor chip, a signal delay preventing region corresponds to a first logic circuit block 22, a CPU block 23, an SRAM block 24, an I/O block 25, a DRAM block 26 and a second logic circuit block 27 alone of a device region 20 (shown in FIG. 1A), and a power line region 30 corresponds to a portion of the device region 20 excluding the first logic circuit block 22, the CPU block 23, the SRAM block 24, the I/O block 25, the DRAM block 26 and the second logic circuit block 27.

A third layout of Embodiment 2 is the same as the third layout of Embodiment 1 described with reference to FIG. 2A, and specifically, a pad region 10 is provided in a peripheral portion of a semiconductor chip, a signal delay preventing region corresponds to a DRAM block 26 alone of a device region 20 (shown in FIG. 1A) and a power line region 30 corresponds to a portion of the device region 20 excluding a first logic circuit block 22, a CPU block 23, an SRAM block 24, an I/O block 25, a DRAM block 26 and a second logic circuit block 27.

The signal delay preventing region may correspond to a memory cell block other than the DRAM block 26, such as an SRAM block and a ROM block.

A fourth layout of Embodiment 2 is the same as the fourth layout of Embodiment 1 described with reference to FIG. 2B, and specifically, a pad region 10 is provided in a peripheral portion of a semiconductor chip, and a signal delay preventing region corresponds to a critical path region 28 alone of a device region 20 (shown in FIG. 1A).

Now, cross-sectional structures of respective layers in the multi-level interconnect structure for embodying the first and second exemplified semiconductor devices of Embodiment 2 will be described.

In a first cross-sectional structure of Embodiment 2, the low-dielectric constant insulating film of FIG. 3 is replaced with an interconnect insulating film having an air gap between the adjacent interconnects in the interconnect layer. In a second cross-sectional structure of Embodiment 2, the low-dielectric constant insulating film of FIG. 4 is replaced with an interconnect insulating film having an air gap between the adjacent interconnects in the interconnect layer. In a third cross-sectional structure of Embodiment 2, the low-dielectric constant insulating film of FIG. 5 is replaced with an interconnect insulating film having an air gap between the adjacent interconnects in the interconnect layer.

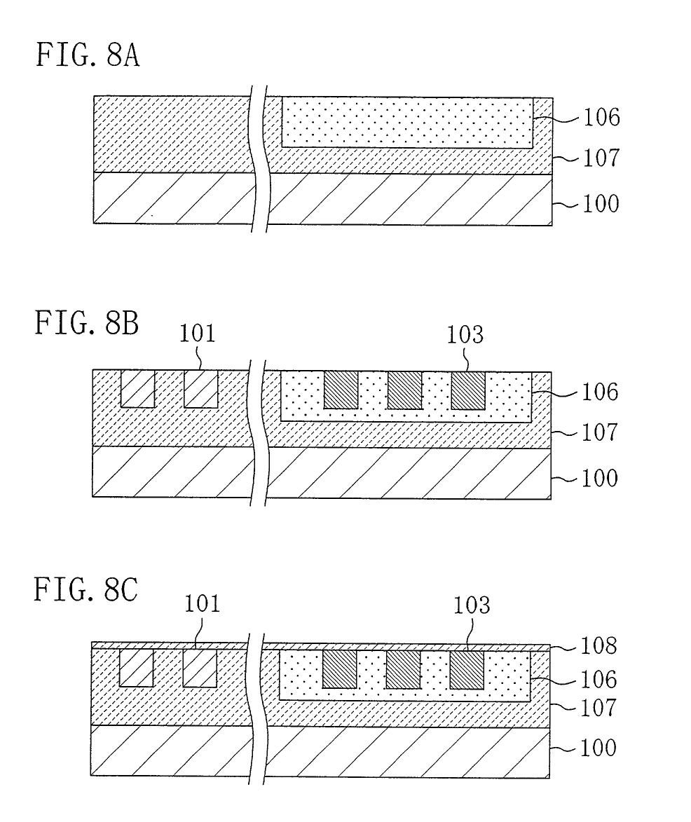

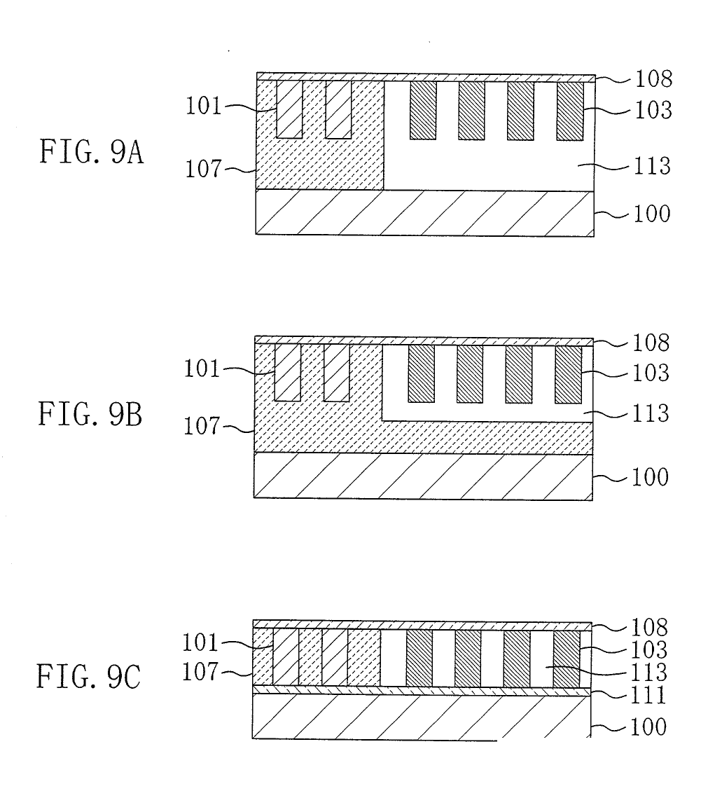

FIGS. 9A through 9C show cross-sectional structures taken on lines different from the first through third cross-sectional structures in a semiconductor device including a power line region and a signal delay preventing region according to Embodiment 2.

In the cross-sectional structure of FIG. 9A, an air gap 113 is formed in the entire signal delay preventing region where signal lines 103 of copper or copper alloy are formed, and an insulating film 107 of any of the aforementioned insulating materials is formed in the entire power line region where power lines 101 of copper or copper alloy are formed. A diffusion preventing layer 108 for preventing diffusion of copper is formed on the power lines 101, the signal lines 103, the air gap 113 and the insulating film 107.

In the cross-sectional structure of FIG. 9B, an air gap 113 is formed below and between signal lines 103 of copper or copper alloy, and an insulating film 107 of any of the aforementioned insulating materials is formed in the power line region where power lines 101 of copper or copper alloy are formed and below the air gap 113. A diffusion preventing layer 108 for preventing diffusion of copper is formed on the power lines 101, the signal line 103, the air gap 113 and the insulating film 107.

In the cross-sectional structure of FIG. 9C, an air gap 113 is formed between signal lines 103 of copper or copper alloy, and an insulating film 107 of any of the aforementioned insulating materials is formed between power lines 101 of copper or copper alloy. A diffusion preventing layer 108 is formed on the power lines 101, the signal lines 103, the air gap 113 and the insulating film 107, and an etching stopper layer 111 is formed below the power lines 101, the signal lines 103, the air gap 113 and the insulating film 107.

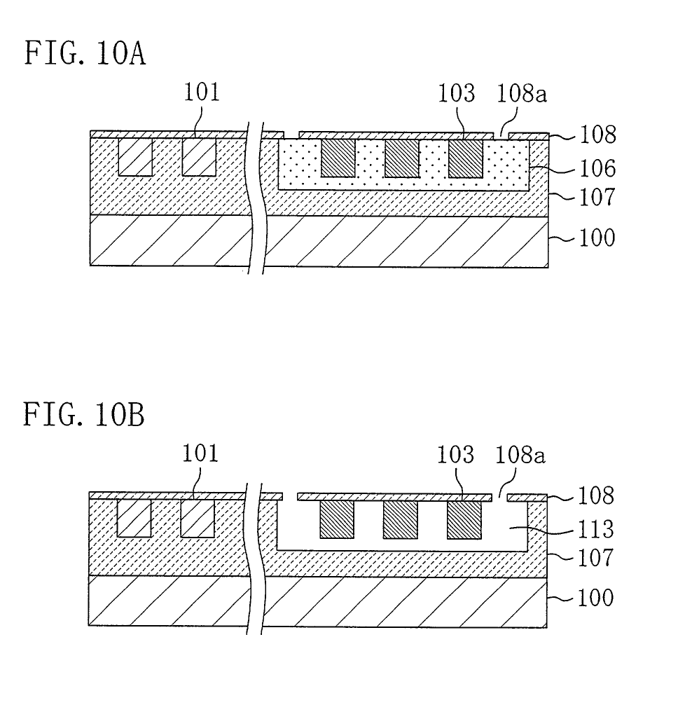

A method for fabricating the semiconductor device of Embodiment 2 having the cross-sectional structure of FIG. 9B will now be described with reference to FIGS. 10A and 10B.

First, through the same procedures in the fabrication method for the semiconductor device having the cross-sectional structure of FIG. 6B, a diffusion preventing layer 108 for preventing diffusion of copper is formed on power lines 101, signal lines 103, a low-dielectric constant film 106 and an insulating film 107 as is shown in FIG. 8C. Thereafter, an opening 108a with an appropriate size is formed in a portion of the diffusion preventing layer 108 formed on the low-dielectric constant insulating film 106 as is shown in FIG. 10A.

Next, an etching gas is supplied through the opening 108 to the low-dielectric constant insulating film 106, so as to remove the low-dielectric constant insulating film 106. Thus, an air gap 113 is formed in a portion from which the low-dielectric constant insulating film 106 has been removed as is shown in FIG. 10B. In the case where the low-dielectric constant insulating film 106 principally includes an organic component, it can be removed by using oxygen plasma.

Since the air gap 113 is formed in the portion where the low-dielectric constant insulating film 106 has been formed, the air gap 113 can be selectively formed by selectively forming the low-dielectric constant insulating film 106.

What is claimed is:

1. A semiconductor device comprising:
an interlayer insulating film formed from a first insulating material between a lower interconnect layer and an upper interconnect layer in a pad region on a semiconductor substrate; and
an interconnect insulating film formed from a second insulating material between adjacent interconnects in an interconnect layer in a signal delay preventing region on said semiconductor substrate,
wherein said first insulating material has higher mechanical strength than said second insulating material, and
said second insulating material has a lower dielectric constant than said first insulating material.

2. The semiconductor device of claim 1,
wherein said first insulating material is sandwiched between adjacent interconnects in one of said upper interconnect layer and said lower interconnect layer in said pad region.

3. The semiconductor device of claim 1,
wherein an interlayer insulating film formed between said interconnect layer and an upper layer or a lower layer in said signal delay preventing region is made from said second insulating material.

4. The semiconductor device of claim 1,
wherein said first insulating material is silicon dioxide, fluorosilicate glass or SiOₓH_{y}C_{z}, wherein 0<x<1, 0<y<1 and 0<z<2, and
said second insulating material is an organic polymer, amorphous carbon or a porous material.

5. The semiconductor device of claim 1,
wherein said first insulating material is silicon dioxide or fluorosilicate glass, and
said second insulating material is SiOₓH_{y}C_{z}, wherein 0<x<1, 0<y<1 and 0<z<2.

6. The semiconductor device of claim 1,
wherein said signal delay preventing region corresponds to a region on said semiconductor substrate excluding said pad region.

7. The semiconductor device of claim 1,
wherein said signal delay preventing region corresponds to a functional block region.

8. The semiconductor device of claim 1,
wherein said signal delay preventing region corresponds to a memory block region.

9. The semiconductor device of claim 1,
wherein said signal delay preventing region corresponds to a critical path region.

10. A semiconductor device comprising:
an interlayer insulating film formed from a first insulating material between a lower interconnect layer and an upper interconnect layer in a power line region on a semiconductor substrate; and
an interconnect insulating film formed from a second insulating material between adjacent interconnects in an interconnect layer in a signal delay preventing region on said semiconductor substrate,
wherein said first insulating material has higher thermal conductivity than said second insulating material, and
said second insulating material has a lower dielectric constant than said first insulating material.

11. The semiconductor device of claim 10,
wherein said first insulating material is sandwiched between adjacent interconnects in one of said upper interconnect layer and said lower interconnect layer in said power line region.

12. The semiconductor device of claim 10,
wherein an interlayer insulating film formed between said interconnect layer and an upper layer or a lower layer in said signal delay preventing region is made from said second insulating material.

13. The semiconductor device of claim 10,
wherein said first insulating material is silicon dioxide, fluorosilicate glass or SiOₓH_{y}C_{z}, wherein 0<x<1, 0<y<1 and 0<z<2, and
said second insulating material is an organic polymer, amorphous carbon or a porous material.

14. The semiconductor device of claim 10,
wherein said first insulating material is silicon dioxide or fluorosilicate glass, and
said second insulating material is SiOₓH_{y}C_{z}, wherein 0<x<1, 0<y<1 and 0<z<2.

15. The semiconductor device of claim 10,
wherein said signal delay preventing region corresponds to a region on said semiconductor substrate excluding said power line region.

16. The semiconductor device of claim 10,
wherein said signal delay preventing region corresponds to a functional block region.

17. The semiconductor device of claim 10,
wherein said signal delay preventing region corresponds to a memory block region.

18. The semiconductor device of claim 10,
wherein said signal delay preventing region corresponds to a critical path region.

19. A semiconductor device comprising:
an interlayer insulating film formed from an insulating material between a lower interconnect layer and an upper interconnect layer in a pad region on a semiconductor substrate; and
an interconnect insulating film having an air gap between adjacent interconnects in an interconnect layer in a signal delay preventing region on said semiconductor substrate.

20. The semiconductor device of claim 19,
wherein said insulating material is sandwiched between adjacent interconnects in one of said upper interconnect layer and said lower interconnect layer in said pad region.

21. The semiconductor device of claim 19,
wherein said signal delay preventing region corresponds to a region on said semiconductor substrate excluding said pad region.

22. The semiconductor device of claim 19,
wherein an interlayer insulating film formed between said interconnect layer and an upper layer or a lower layer in said signal delay preventing region is made from a material having a lower dielectric constant than said insulating material.

23. The semiconductor device of claim 19,
wherein said signal delay preventing region corresponds to a functional block region.

24. The semiconductor device of claim 19,
wherein said signal delay preventing region corresponds to a memory block region.

25. The semiconductor device of claim 19,
wherein said signal delay preventing region corresponds to a critical path region.

26. A semiconductor device comprising:
an interlayer insulating film formed from an insulating material between a lower interconnect layer and an upper interconnect layer in a power line region on a semiconductor substrate; and
an interconnect insulating film having an air gap between adjacent interconnects in an interconnect layer in a signal delay preventing region on said semiconductor substrate.

27. The semiconductor device of claim 26,
wherein said insulating material is sandwiched between adjacent interconnects in one of said upper interconnect layer and said lower interconnect layer in said power line region.

28. The semiconductor device of claim 26,
wherein an interlayer insulating film formed between said interconnect layer and an upper layer or a lower layer in said signal delay preventing region is made from a material having a lower dielectric constant than said insulating material.

29. The semiconductor device of claim 26,
wherein said signal delay preventing region corresponds to a region on said semiconductor substrate excluding said power line region.

30. The semiconductor device of claim 26,
wherein said signal delay preventing region corresponds to a functional block region.

31. The semiconductor device of claim 26,
wherein said signal delay preventing region corresponds to a memory block region.

32. The semiconductor device of claim 26,
wherein said signal delay preventing region corresponds to a critical path region.
